(19) United States
(12) Patent Application Publication
(10) Pub. No.: US 2026/0150691 A1
(43) Pub. Date: May 28, 2026

(54) SEMICONDUCTOR DEVICES COMPRISING RECESS PORTION AND SEMICONDUCTOR PACKAGES HAVING THE SAME

(71) Applicant: Samsung Electronics Co., Ltd., Suwon-si (KR)

(72) Inventors: Hongseok CHOI, Suwon-si (KR); Okkyu LEE, Suwon-si (KR)

(73) Assignee: Samsung Electronics Co., Ltd., Suwon-si (KR)

(21) Appl. No.: 19/345,500

(22) Filed: Sep. 30, 2025

(30) Foreign Application Priority Data
Nov. 25, 2024 (KR) 10-2024-0169821

(51) Int. Cl. H01L 23/00; H01L 23/48; H01L 23/544; H01L 23/58; H01L 25/065

(52) U.S. Cl. CPC H10W 42/121; H10W 20/20; H10W 42/00; H10W 46/00; H10W 90/00; H10W 90/722

(57) ABSTRACT

A semiconductor device includes an upper structure including a semiconductor substrate having a device region and an edge region on at least one side of the device region, a lower structure on the upper structure, the lower structure including a device layer, the device layer including a conductive structure and a first insulating layer covering the conductive structure, an interconnection layer on the device layer, the interconnection layer including a plurality of conductive pattern layers and a second insulating layer covering the plurality of conductive pattern layers, and a side surface of the upper structure and a side surface of the lower structure define a plurality of recess portions in the edge region.

### CROSS-REFERENCE TO RELATED APPLICATION(S)

This application claims benefit of priority to Korean Patent Application No. 10-2024-0169821 filed on Nov. 25, 2024 in the Korean Intellectual Property Office, the disclosure of which is incorporated herein by reference in its entirety.

### BACKGROUND

The present inventive concepts relate to semiconductor devices and semiconductor packages including the same.

Demand for performance, stability, or the like, in semiconductor devices, is increasing. In addition, performance and stability of semiconductor devices mounted in semiconductor packages are desired. Various technologies are desired for manufacturing semiconductor devices in line with the performance and stability trends. In particular, the need for technologies for improving reliability and/or a dicing property of semiconductor devices is desired.

### SUMMARY

Some example embodiments of the present inventive concepts provide semiconductor devices having improved reliability, and semiconductor packages including the same.

According to an example embodiment of the present inventive concepts, a semiconductor device includes an upper structure including a semiconductor substrate having a device region and an edge region on at least one side of the device region, a lower structure on the upper structure, the lower structure including a device layer, the device layer including a conductive structure and a first insulating layer covering the conductive structure, an interconnection layer being on the device layer, the interconnection layer including a plurality of interconnection pattern layers and a second insulating layer covering the plurality of interconnection pattern layers, a first through-electrode extending through the semiconductor substrate and the first insulating layer of the device layer and electrically connected to at least one interconnection pattern layer among the plurality of interconnection pattern layers, and a second through-electrode extending through the semiconductor substrate, the first insulating layer of the device layer, and the second insulating layer of the interconnection layer, wherein at least one of a side surface of the upper structure or a side surface of the lower structure defines at least one recess portion in the edge region.

According to an example embodiment of the present inventive concepts, a semiconductor device includes an upper structure including a semiconductor substrate having a device region and an edge region on at least one side of the device region, and a lower structure on the upper structure, the lower structure including a device layer, the device layer including a conductive structure and a first insulating layer covering the conductive structure, an interconnection layer being on the device layer, the interconnection layer including a plurality of conductive pattern layers and a second insulating layer covering the plurality of conductive pattern layers, wherein a side surface of the upper structure and a side surface of the lower structure define a plurality of recess portions in the edge region.

According to an example embodiment of the present inventive concepts, a semiconductor device includes a semiconductor substrate including a device region and an edge region surrounding the device region, a device layer on the semiconductor substrate, the device layer including a conductive structure and a first insulating layer covering the conductive structure; an interconnection layer on the device layer, the interconnection layer including a plurality of conductive pattern layers that are vertically stacked and a second insulating layer covering the plurality of conductive pattern layers, and a through-electrode extending through the semiconductor substrate, the first insulating layer of the device layer, and the second insulating layer of the interconnection layer, wherein the edge region includes a recess portion in the edge region, the recess portion including a first portion defined by a side surface of the semiconductor substrate, and a first step difference is defined between a side surface of the first portion and a side surface of the first insulating layer.

### BRIEF DESCRIPTION OF DRAWINGS

The and other aspects, features, and advantages of the present inventive concepts will be more clearly understood from the following detailed description, taken in conjunction with the accompanying drawings, in which:

FIG. 1 is a plan view illustrating a semiconductor substrate including a semiconductor device according to an example embodiment.

FIG. 2 is a partial enlarged view of portion ‘A’ of FIG. 1.

FIG. 3A is a cross-sectional view of FIG. 2, taken along line I-I′, and FIG. 3B is a cross-sectional view illustrating a portion of a semiconductor device according to an example embodiment.

FIG. 4 is a partial enlarged view illustrating portion ‘B’ of FIG. 3B.

FIGS. 5 and 6 are partial enlarged views illustrating a semiconductor device according to a modified example. FIGS. 5 and 6 are partial enlarged views illustrating portion ‘B’ of FIG. 3B.

FIG. 7A is a cross-sectional view of FIG. 2, taken along line I-I′, and FIG. 7B is a cross-sectional view illustrating a portion of a semiconductor device according to an example embodiment.

FIG. 8 is a partial enlarged view illustrating portion ‘B’ of FIG. 3B.

FIG. 9 is a partial enlarged view illustrating a semiconductor device according to a modified example. FIG. 9 is a partial enlarged view illustrating portion ‘B’ of FIG. 3B.

FIG. 10A is a plan view illustrating a semiconductor package according to an example embodiment.

FIG. 10B is a cross-sectional view of the semiconductor package of FIG. 10A, taken along line II-II′.

FIG. 11A is a plan view illustrating a semiconductor package according to an example embodiment.

FIG. 11B is a cross-sectional view of the semiconductor package of FIG. 11A, taken along line III-III′.

FIGS. 12 to 16 are cross-sectional views illustrating a process sequence for explaining a method of manufacturing a semiconductor package according to an example embodiment.

### DETAILED DESCRIPTION

Hereinafter, terms such as ‘on,’ ‘upper,’ ‘upper portion,’ ‘upper surface,’ ‘below,’ ‘lower,’ ‘lower portion,’ ‘lower surface,’ ‘side surface,’ ‘upper end,’ ‘lower end’ and the like can be understood to refer to the drawings, except in cases in which they are indicated separately by drawing symbols. Terms such as “upper,” “upper portion,” “intermediate,” “lower,” “lower portion,” and the like may be replaced with other terms, such as “first,” “second,” “third,” and the like, and used to describe components of the specification. Terms such as “first,” “second,” “third,” and the like may be used to describe various components, but components are not limited by the terms, and “first component” may be named “second component.”

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, some example embodiments will be described as follows with reference to the attached drawings.

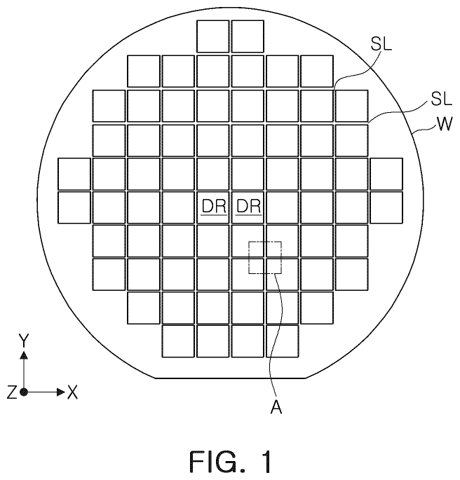

FIG. 1 is a plan view illustrating a semiconductor substrate including a semiconductor device according to an example embodiment.

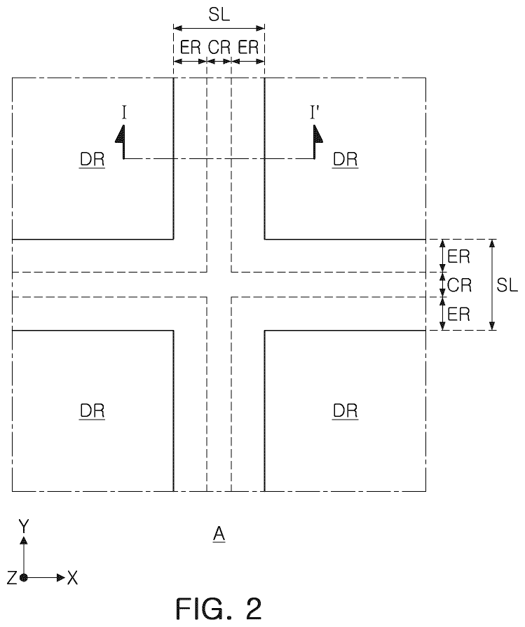

FIG. 2 is a partial enlarged view of portion ‘A’ of FIG. 1.

Referring to FIGS. 1 and 2, a semiconductor substrate W may include device regions DR and a scribe line region SL between the device regions DR. Scribe line regions SL may extend in a first horizontal direction (e.g., X-direction) and a second horizontal direction (e.g., Y-direction), intersecting the first horizontal direction. The device regions DR may be spaced apart from each other in the first horizontal direction and the second horizontal direction, and may be surrounded by the scribe line regions SL. The device regions DR may be separated along the scribe line regions SL by a dicing process, to be described below, to form a semiconductor element. The scribe line regions SL may include a cutting region CR cut by the dicing process, and edge regions ER between the cutting region CR and the device regions DR. The edge regions ER may surround the device regions DR, respectively.

In an example embodiment, a device region DR may be provided with a volatile memory element such as a dynamic random access memory (DRAM), a static random access memory (SRAM), or the like, or a non-volatile memory element such as a phase-change random access memory (PRAM), a magnetoresistive random access memory (MRAM), a ferroelectric random access memory (FeRAM), or a resistive random access memory (RRAM). In an example embodiment, the device region DR may be provided with a logic device such as a microprocessor, an analog device, or a digital signal processor.

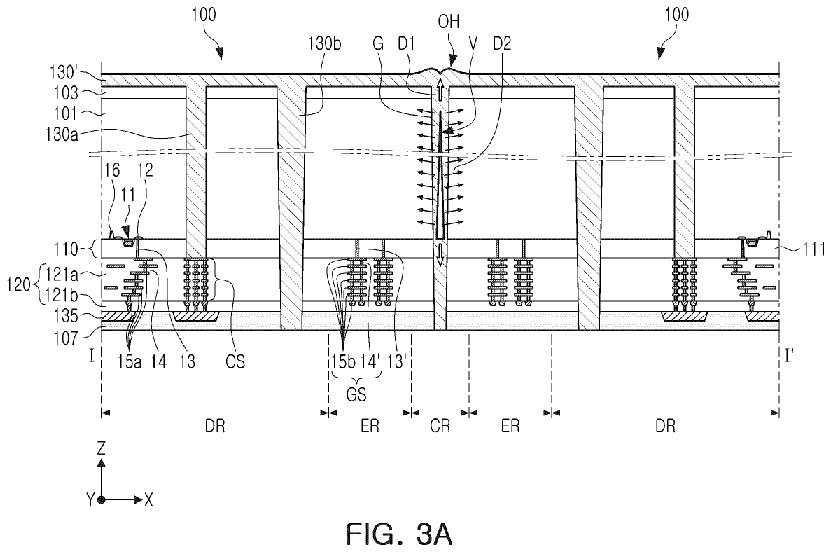

FIG. 3A is a cross-sectional view of FIG. 2, taken along line I-I′, and FIG. 3B is a cross-sectional view illustrating a portion of a semiconductor device according to an example embodiment.

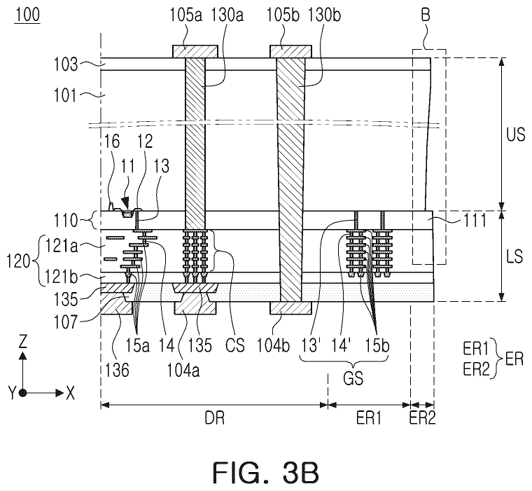

FIG. 4 is a partial enlarged view illustrating portion ‘B’ of FIG. 3B.

Referring to FIGS. 3A, 3B, and 4, a semiconductor device 100 may include a semiconductor substrate 101, a device layer 110, and an interconnection layer 120. The semiconductor substrate 101 may correspond to the semiconductor substrate W illustrated in FIG. 1. In an example embodiment, a region including the semiconductor substrate 101 may be referred to as an upper structure US, and a region including the device layer 110 and the interconnection layer 120 may be referred to as a lower structure LS.

The semiconductor substrate 101 may include device regions DR and a scribe line region SL between the device regions DR. The scribe line region SL may include edge regions ER and a cutting region CR between the edge regions ER. An edge region ER may surround a device region DR. The cutting region CR may refer to a portion that may be separated during a dicing process to be described below. After the dicing process to be described below, for convenience, the edge region ER may be referred to as a first edge region ER1, and the cutting region CR may be referred to as a second edge region ER2.

The semiconductor substrate 101 may include a semiconductor material. For example, the semiconductor substrate 101 may be a silicon substrate, a germanium substrate, a silicon germanium substrate, or a silicon-on-insulator (SOI) substrate. The semiconductor substrate 101 may include a semiconductor material such as a group IV semiconductor, a group III-V compound semiconductor, or a group II-VI compound semiconductor. The semiconductor substrate 101 may include a conductive region 12 and an isolation region 16. The conductive region 12 may be, for example, a well doped with an impurity, or a structure doped with an impurity. The isolation region 16 may include a device isolation structure having a shallow trench isolation (STI) structure, and may include silicon oxide.

The upper structure US may further include a back protective layer 103. The back protective layer 103 may be formed on an upper surface of the semiconductor substrate 101, and may protect the semiconductor substrate 101. The back protective layer 103 may be formed as an insulating layer such as a silicon oxide film, a silicon nitride film, a silicon oxynitride film, or the like, but a material of the back protective layer 103 is not limited to those materials. For example, the back protective layer 103 may be formed of a polymer such as polyimide (PI) or photosensitive polyimide (PSPI).

The device layer 110 may include an insulating layer 111 and integrated circuit devices 11. In an example embodiment, the insulating layer 111 may be referred to as a first insulating layer. The insulating layer 111 may cover the semiconductor substrate 101 and the integrated circuit devices 11. The insulating layer 111 may include silicon oxide, silicon nitride, silicon oxynitride, or a combination thereof. For example, the insulating layer 111 may include silicon oxide. The insulating layer 111 may include a material having a coefficient of thermal expansion that is smaller than a coefficient of thermal expansion of a material of the semiconductor substrate 101. The integrated circuit devices 11 may be disposed in the device region DR. The integrated circuit devices 11 may include a memory cell array including switching elements and data storage elements, logic elements including a MOSFET, a capacitor, and/or a resistor. The integrated circuit devices 11 may include, for example, various active components and/or passive components such as a FET (e.g., a planar FET, a FinFET, or the like), a memory element (e.g., a flash memory, a DRAM, an SRAM, an EEPROM, a PRAM, an MRAM, an FeRAM, an RRAM, or the like), a logic element (e.g., an AND, an OR, a NOT, or the like), a system LSI, a CMOS image sensor (CIS), or a micro electric mechanical systems (MEMS).

The device layer 110 may further include a plurality of connection layers 13 and 13′. A first connection layer 13 may be electrically connected to the conductive region 12 in the device region DR, and a second connection layer 13′ may be connected to a guard-ring structure GS in the edge region ER. In an example embodiment, the plurality of connection layers 13 and 13′ may be referred to as conductive structures.

The interconnection layer 120 may be formed on the device layer 110. The interconnection layer 120 may include a plurality of conductive pattern layers 15a and 15b disposed on different levels in a vertical direction, and an interlayer insulating layer 121a and an insulating layer 121b covering the plurality of conductive pattern layers 15a and 15b. In an example embodiment, the interlayer insulating layer 121a and/or the insulating layer 121b may be referred to as a second insulating layer. The plurality of conductive pattern layers 15a and 15b may include interconnection pattern layers 15a disposed in the device region DR and dummy pattern layers 15b disposed in the edge region ER. The dummy pattern layers 15b may be guard-ring pattern layers. In an example embodiment, at least a portion of the dummy pattern layers 15b may also be disposed in the cutting region CR (or the second edge region ER2) (not illustrated).

The interlayer insulating layer 121a may surround the plurality of conductive pattern layers 15a and 15b, and may include a low-κ dielectric material having a low dielectric constant. For example, the interlayer insulating layer 121a may include silicon oxide or an organic polymer, doped with impurities. In an example embodiment, the interlayer insulating layer 121a may include SiOCH, SiCN, or a combination thereof. The interlayer insulating layer 121a may include a material having a coefficient of thermal expansion, greater than the coefficient of thermal expansion of the material of the insulating layer 111. In an example embodiment, the interlayer insulating layer 121a may include a plurality of insulating layers sequentially stacked on the insulating layer 111. Depending on a process, a boundary between the interlayer insulating layers may not be clearly distinguished. Among interlayer insulating layers 121a, a lowermost interlayer insulating layer 121a (e.g., portion covering a lowermost conductive pattern layer) may include a different material from an interlayer insulating layer 121a therebelow. For example, the lowermost interlayer insulating layer 121a may include silicon oxide.

The insulating layer 121b may include a plurality of insulating layers sequentially stacked on the interlayer insulating layer 121a. Depending on a process, a boundary between the interlayer insulating layers may not be clearly distinguished. The insulating layer 121b may cover lowermost pattern layers among the plurality of conductive pattern layers 15a and 15b. The insulating layer 121b may include silicon nitride, silicon oxynitride, silicon carbonitride, or a combination thereof. The insulating layer 121b may include a material having a coefficient of thermal expansion, greater than the coefficient of thermal expansion of the material of the insulating layer 111.

The plurality of conductive pattern layers 15a and 15b may include copper (Cu), aluminum (Al), tungsten (W), nickel (Ni), titanium (Ti), titanium nitride (TiN), tantalum (Ta), tantalum nitride (TaN), gold (Au), or a combination thereof. For example, uppermost pattern layers may include aluminum (Al), and pattern layers therebelow may include copper (Cu). At least a portion of the plurality of conductive pattern layers 15a and 15b may include a plurality of patterns spaced apart in the horizontal direction. In the present specification, the ‘pattern layer’ can be understood to collectively refer to ‘patterns’ disposed on the same level. The ‘patterns’ may include an interconnection extending in the horizontal direction, and a pad connected to the interconnection. At least a portion of the plurality of conductive pattern layers 15a and 15b may be vertically connected through-vias 14 and 14′.

According to an example embodiment, the interconnection layer 120 may further include the guard-ring structure GS. The guard-ring structure GS may surround the device region DR. For example, the guard-ring structure GS may extend in the horizontal direction to surround an interconnection structure CS (or second through-electrode 130b) in the edge region ER. The guard-ring structure GS may include guard-ring pattern layers 15b vertically stacked and/or guard-ring via layers 14′ vertically connecting the guard-ring pattern layers 15b. The guard-ring pattern layers 15b may include the same material as the plurality of interconnection pattern layers 15a corresponding thereto in the horizontal direction.

The lower structure LS may further include a front protective layer 107 and a conductive pattern 135, on the interconnection layer 120. The conductive pattern 135 may be connected to the interconnection structure CS through a conductive via. The conductive via may vertically penetrate the insulating layer 121b. The conductive pattern 135 and the conductive via may include the same material, but are not limited thereto.

The front protective layer 107 may include a single-layer insulating film or multiple layer insulating films. For example, the front protective layer 107 may include silicon nitride, silicon oxynitride, silicon carbonitride, or a combination thereof. In an example embodiment, the front protective layer 107 may include tetraethyl orthosilicate (TEOS).

The conductive pattern 135 may include, for example, a ground pad, a power pad, an AC pad, a data pad, and a DC pad. The ground pad may be a pad for providing a reference potential for circuit operation of the semiconductor device 100. The power pad may be a pad for supplying power for circuit operation. The AC pad may be a pad for supplying AC power to the semiconductor device or receiving a signal for performing an AC test. The data pad may be pads for input/output of a logic signal or data. The DC pad may be a pad for measuring a potential level of a specific location of the semiconductor device.

A lower pad 136 may be disposed below the conductive pattern 135. The lower pad 136 may include a via portion connected to the conductive pattern 135 by penetrating at least a portion of the front protective layer 107, and a pad portion covering the via portion on the front protective layer 107.

The semiconductor device 100 may further include a plurality of through-hole electrodes 130a and 130b. The plurality of through-hole electrodes 130a and 130b may include first and second through-hole electrodes 130a and 130b penetrating the upper structure US and extending through a portion of the lower structure LS.

The first through-hole electrode 130a may extend through the back protective layer 103, the semiconductor substrate 101, and the insulating layer 111 of the device layer 110. The first through-hole electrode 130a may include a conductive plug and a barrier film (not illustrated) surrounding the same. The conductive plug may include a metal material, for example, tungsten (W), titanium (Ti), aluminum (Al), or copper (Cu). The conductive plug may be formed by a plating process, a PVD process, or a CVD process. The barrier film may include titanium (Ti), titanium nitride (TiN), tantalum (Ta), or tantalum nitride (TaN), and may be formed by a plating process, a PVD process, or a CVD process.

The semiconductor device 100 may further include a first back pad 105a disposed at a back side of the semiconductor substrate 101. The first back pad 105a may be in contact with an upper surface of the first through-electrode 130a on the back protective layer 103. The first back pad 105a may include a metal material. The first back pad 105a may include, for example, at least one of aluminum (Al), copper (Cu), nickel (Ni), tungsten (W), platinum (Pt), or gold (Au).

The interconnection layer 120 may further include an interconnection structure CS disposed below the first through-electrode 130a. The interconnection structure CS may include a plurality of interconnection pattern layers 15a vertically stacked on the device region DR. The interconnection structure CS may be electrically connected to the first through-electrode 130a and/or the first back pad 105a by an uppermost interconnection pattern layer 15a. Although not illustrated, the interconnection structure CS may be electrically connected to the conductive region 12 and/or the integrated circuit device 11 by a conductive structure 13.

The semiconductor device 100 may further include a first front pad 104a disposed at a front side of the semiconductor substrate 101. The first front pad 104a may be disposed below the interconnection structure CS (or first through-electrode 130a). The first front pad 104a may include a via portion connected to the conductive pattern 135 by penetrating at least a portion of the front protective layer 107, and a pad portion on the front protective layer 107 and covering the via portion. The first front pad 104a may include substantially the same material as the first back pad 105a.

The second through-electrode 130b may penetrate the upper structure US and the lower structure LS. The second through-hole electrode 130b may extend, for example, through the back protective layer 103, the semiconductor substrate 101, the insulating layer 111 of the device layer 110, the insulating layers (121a and 121b) of the interconnection layer 120, and the front protective layer 107. The second through-hole electrode 130b may have a structure similar to that of the first through-hole electrode 130a. The second through-hole electrode 130b may include a metal material, for example, tungsten (W), titanium (Ti), aluminum (Al), or copper (Cu). The second through-hole electrode 130b may be formed by a plating process, a PVD process, or a CVD process. From another view, unlike the first through-hole electrode 130a, the second through-hole electrode 130b may not include a barrier film.

The second through-electrode 130b may be electrically connected to at least one of a plurality of interconnection pattern layers 15a (not illustrated). According to an example embodiment, the second through-electrode 130b may be a heat dissipation structure.

The semiconductor device 100 may further include a second back pad 105b disposed at the back side of the semiconductor substrate 101. The second back pad 105b may be in contact with an upper surface of the second through-electrode 130b on the back protective layer 103. The second back pad 105b may be on substantially the same level as the first back pad 105a with respect to the back protective layer 103. The second back pad 105b may include substantially the same material as the first back pad 105a.

The semiconductor device 100 may further include a second front pad 104b disposed at the front side of the semiconductor substrate 101. The second front pad 104b may be in contact with a lower surface of the second through-electrode 130b on the front protective layer 107. The second front pad 104b may be on substantially the same level as the first front pad 104a with respect to the front protective layer 107. The second front pad 104b may include substantially the same material as the first front pad 104a.

The first and second through-hole electrodes 130a and 130b may have a tapering structure. For example, widths of the first and second through-hole electrodes 130a and 130b in the horizontal direction (e.g., X-direction and/or Y-direction) may gradually decrease from an upper surface of the upper structure US to a lower surface of the lower structure LS, but are not limited thereto. For example, the widths of the first and second through-hole electrodes 130a and 130b in the horizontal direction may gradually increase from the upper surface of the upper structure US to the lower surface of the lower structure LS (not illustrated).

A length of the first through-hole electrode 130a in the vertical direction (e.g., Z-direction) may be smaller than a length of the second through-hole electrode 130b in the vertical direction.

At least one recess portion RP may be defined in the edge region ER (or second edge region ER2). For example, the recess portion RP may be formed on a side surface of the upper structure US.

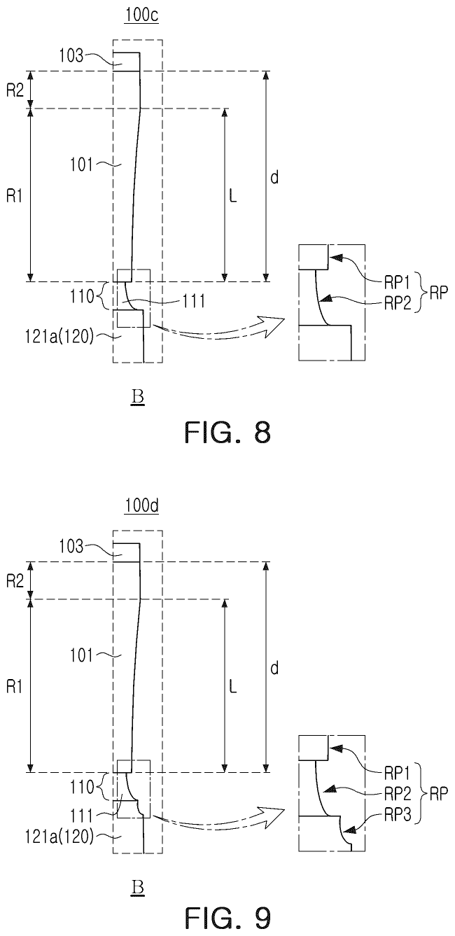

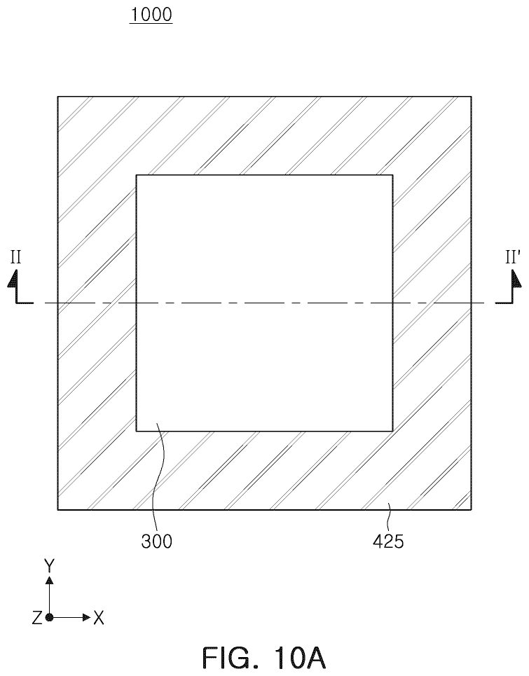

The at least one recess portion RP may include a plurality of recess portions (e.g., RP1, RP2 in FIG. 8). In this case, at least a portion of the plurality of recess portions (e.g., RP1 in FIG. 8) may be formed on a side surface of the upper structure US, and a remaining portion of the plurality of recess portions (e.g., RP2 in FIG. 8 or RP2 and RP3 in FIG. 9) may be formed on a side surface of the lower structure LS (see FIGS. 8 and 9).

The recess portion RP may be formed on a side surface of the semiconductor substrate 101. The side surface of the semiconductor substrate 101 may include a first region R1 in which the recess portion RP is formed, and a second region R2 in which the recess portion RP is not formed. The first region R1 may be adjacent to the device layer 110, and the second region R2 may be adjacent to the back protective layer 103.

A maximum length L of the recess portion RP in the vertical direction (e.g., Z-direction) on the first region R1 may be smaller than a thickness d of the semiconductor substrate 101 in the vertical direction. A ratio L/d of the maximum length L to the thickness d may be about 0.3 or greater. In an example embodiment, the ratio L/d may be in a range of about 0.3 to about 0.9. In an example embodiment, the ratio L/d may be in a range of about 0.4 to about 0.8.

A width of the recess portion RP in the horizontal direction (e.g., X-direction and/or Y-direction) may increase toward an upper surface of the lower structure LS (or device layer 110). From another view, in the first region R1, a width of the semiconductor substrate 101 in the horizontal direction may decrease toward the upper surface of the lower structure LS (or device layer 110).

A side surface of the upper structure US and a side surface of the lower structure LS may have a step difference. The step difference may be due to the recess portion RP. For example, a side surface of the semiconductor substrate 101 recessed by the recess portion RP and a side surface of the device layer 110 (or first insulating layer 111) may have a step difference. Due to the step difference, an edge of an upper surface of the device layer 110 may be exposed.

According to some example embodiments of the present inventive concepts, the recess portion RP may be due to expansion of a void V due to a difference in coefficient of thermal expansion between a conductive material layer 130′ (FIG. 3A) formed in a dicing groove G (FIG. 3A) in the cutting region CR of the scribe lane SL in a dicing process, and a material included in the semiconductor substrate 101 adjacent to the conductive material layer 130′.

According to some example embodiments of the present inventive concepts, the dicing process may include an annealing process performed within a desired (or alternatively, predetermined) temperature management range. During the annealing process, due to the difference in coefficient of thermal expansions, the void V may expand in a second direction D2 perpendicular to a surface (or a boundary) thereof. In other words, the void V may expand in a direction parallel to a horizontal direction (e.g., X-direction). Therefore, stress due to the expanded void V may be transmitted in a first direction D1 parallel to a longitudinal direction (e.g., Z-direction).

From another view, the semiconductor substrate 101 may be divided into a plurality of semiconductor chips 100 by the stress transmitted in the first direction D1, and therefore, a separate laser irradiation process and a separate dicing machine may not be needed in the dicing process of some example embodiments of the present inventive concepts. In addition, the recess portion RP may be defined on the side surface of the semiconductor device 100 by the void V expanded in the second direction D2.

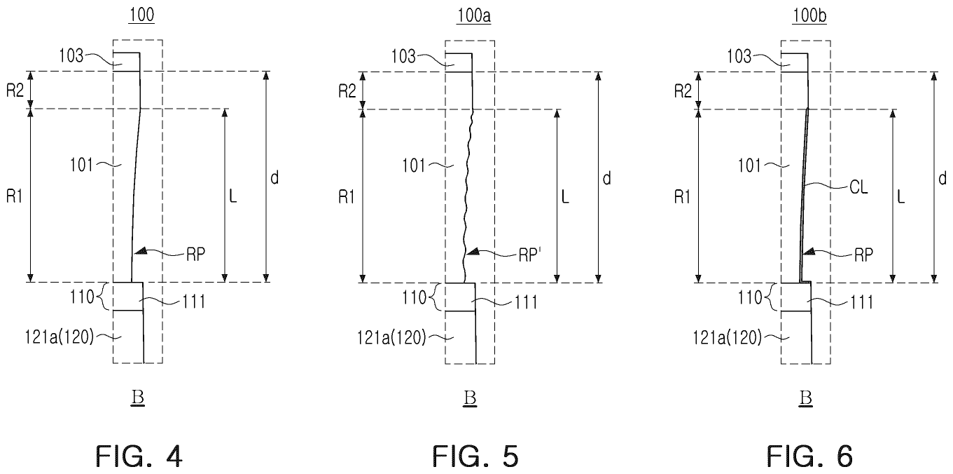

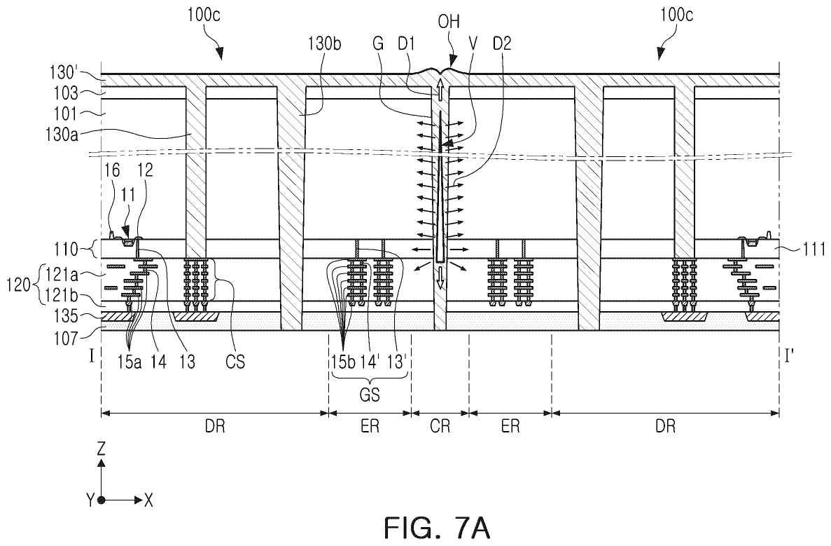

FIGS. 5 and 6 are partial enlarged views illustrating a semiconductor device according to a modified example. FIGS. 5 and 6 are partial enlarged views illustrating portion ‘B’ of FIG. 3B.

Referring to FIG. 5, a semiconductor substrate 101 of a semiconductor device 100a may be the same as or similar to that described with reference to FIGS. 1 to 4, except that surface roughness in a first region R1 is different from surface roughness in a second region R2.

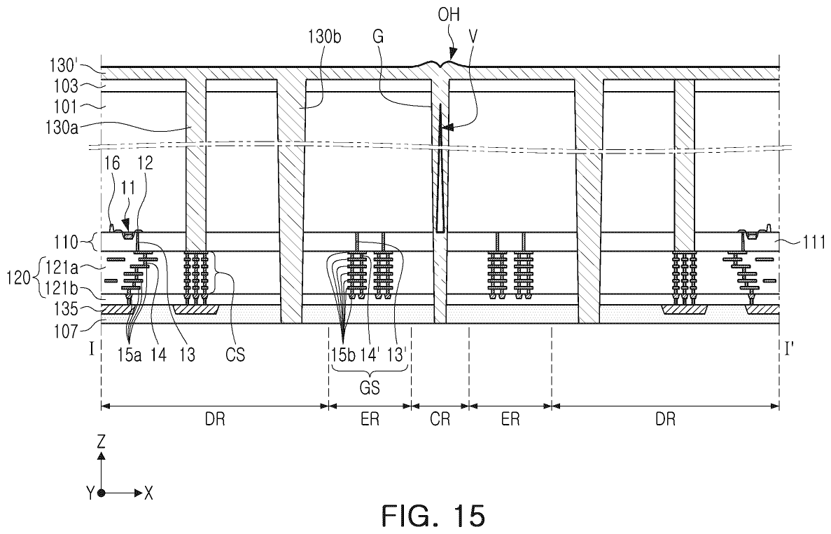

The surface roughness of the semiconductor substrate 101 in the first region R1 may be greater than the surface roughness of the semiconductor substrate in the second region R2. This may be interpreted as being because the void V (FIG. 3A) does not expand evenly in the second direction D2. In this case, the fact that the void does not expand evenly may be interpreted as being because a conductive material layer 130′ (FIG. 15) is not conformally formed along a sidewall of a dicing groove G (FIG. 15).

Referring to FIG. 6, a semiconductor device 100b may be the same as or similar to that described with reference to FIGS. 1 to 5, except that a conductive material layer CL may remain on at least a portion of a side surface of a semiconductor substrate 101.

The conductive material layer CL may remain in a first region R1. The conductive material layer CL may be disposed, for example, on a surface of a recess portion RP and an upper surface of a device layer 110 in the first region R1. The conductive material layer CL may be due to a conductive material layer 130′ that has not been completely removed after a dicing process.

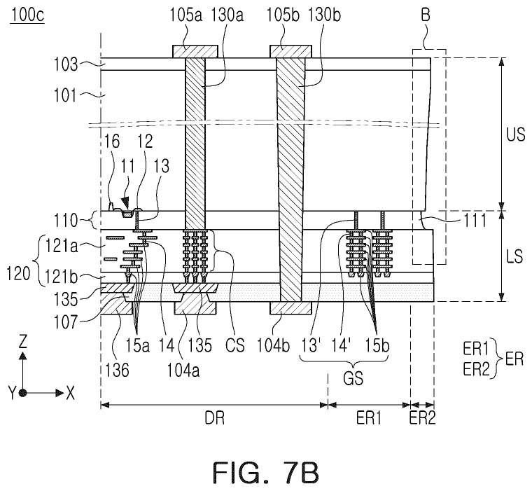

FIG. 7A is a cross-sectional view of FIG. 2, taken along line I-I′, and FIG. 7B is a cross-sectional view illustrating a portion of a semiconductor device according to an example embodiment.

FIG. 8 is a partial enlarged view illustrating portion ‘B’ of FIG. 3B.

Referring to FIGS. 7A, 7B, and 8, a semiconductor device 100c may be the same as or similar to that described with reference to FIGS. 1 to 6, except that at least one recess portion RP may include a plurality of recess portions RP1 and RP2.

The plurality of recess portions RP1 and RP2 may include a first recess portion RP1 formed on a side surface of an upper structure US, and a second recess portion RP2 formed on a side surface of a lower structure LS. For example, the first recess portion RP1 may be formed on a side surface of a semiconductor substrate 101, and the second recess portion RP2 may be formed on a side surface of a device layer 110 (or first insulating layer 111).

A maximum width of the second recess portion RP2 in the horizontal direction (e.g., X-direction and/or Y-direction) may be greater than a maximum width of the first recess portion RP1 in the horizontal direction. This may be because a difference in coefficient of thermal expansion between a conductive material layer 130′ (FIG. 15) and a first insulating layer 111 in a dicing groove G (FIG. 15) may be greater than a difference in coefficient of thermal expansion between the conductive material layer 130′ and the semiconductor substrate 101. From another view, it may be because the first insulating layer 111 includes a material having a coefficient of thermal expansion that is smaller than a coefficient of thermal expansion of a material of the semiconductor substrate 101.

A length of the second recess portion RP2 in the vertical direction (e.g., Z-direction) may be smaller than a length L of the first recess portion RP1 in the vertical direction.

A plurality of step differences may be defined on the side surface of the upper structure US and the side surface of the lower structure LS. For example, a first step difference may be formed between the side surface of the semiconductor substrate 101 recessed by the first recess portion RP1 and a side surface of the device layer 110 (or first insulating layer 111) recessed by the second recess portion RP2. In addition, a second step difference may be formed between the side surface of the device layer 110 (or first insulating layer 111) recessed by the second recess portion RP2 and the side surface of the interconnection layer 120 (or second insulating layer 121a).

From another view, the recess portion RP of the present example embodiment may be defined as having a plurality of portions (RP1 and RP2). For example, the recess portion RP may be defined as including a first portion (RP1) formed on the side surface of the upper structure US, and a second portion (RP2) formed on the side surface of the lower structure LS.

FIG. 9 is a partial enlarged view illustrating a semiconductor device according to a modified example. FIG. 9 is a partial enlarged view illustrating portion ‘B’ of FIG. 3B.

Referring to FIG. 9, a semiconductor device 100d may be the same as or similar to that described with reference to FIGS. 1 to 8, except that at least one recess portion RP may include a plurality of recess portions RP1, RP2, and RP3.

The plurality of recess portions RP1, RP2, and RP3 may include a first recess portion RP1 formed on a side surface of an upper structure US, and second and third recess portions RP2 and RP3 formed on a side surface of a lower structure LS.

For example, the first recess portion RP1 may be formed on a side surface of a semiconductor substrate 101, the second recess portion RP2 may be formed on a side surface of a device layer 110 (or first insulating layer 111), and the third recess portion RP3 may be formed on a side surface of an interconnection layer 120 (or second insulating layer 121a).

A maximum width of the second recess portion RP2 in the horizontal direction (e.g., X-direction and/or Y-direction) may be greater than a maximum width of the first recess portion RP1 in the horizontal direction. This may be because a difference in coefficient of thermal expansion between a conductive material layer 130′ (FIG. 15) and a first insulating layer 111 in a dicing groove G (FIG. 15) is greater than a difference in coefficient of thermal expansion between the conductive material layer 130′ and the semiconductor substrate 101. From another view, it may be because the first insulating layer 111 includes a material having a coefficient of thermal expansion that is smaller than a coefficient of thermal expansion of a material of the semiconductor substrate 101.

A maximum width of the third recess portion RP3 in the horizontal direction (e.g., X-direction and/or Y-direction) may be smaller than the maximum width of the second recess portion RP2 in the horizontal direction. This may be because a difference in coefficient of thermal expansion between the conductive material layer 130′ (FIG. 15) and the second insulating layer 121a in the dicing groove G (FIG. 15) may be smaller than a difference in coefficient of thermal expansion between the conductive material layer 130′ and the first insulating layer 111. From another view, it may be because the second insulating layer 121a includes a material having a coefficient of thermal expansion that is greater than a coefficient of thermal expansion of a material of the first insulating layer 111.

A plurality of step differences may be defined on the side surface of the upper structure US and the side surface of the lower structure LS. For example, a first step difference may be formed between the side surface of the semiconductor substrate 101 recessed by the first recess portion RP1 and a side surface of the device layer 110 (or first insulating layer 111) recessed by the second recess portion RP2. In addition, a second step difference may be formed between the side surface of the device layer 110 (or first insulating layer 111) recessed by the second recess portion RP2 and the side surface of the interconnection layer 120 (or second insulating layer 121a) recessed by the third recess portion RP3.

Similar to those described above, the recess portion RP of the present example embodiment may be defined as having the plurality of portions (RP1, RP2, and RP3). For example, the recess portion RP may be defined as including a first portion (RP1) formed on the side surface of the upper structure US, a second portion (RP2) formed on the side surface of the device layer 110, and a third portion (RP3) formed on the side surface of the interconnection layer 120.

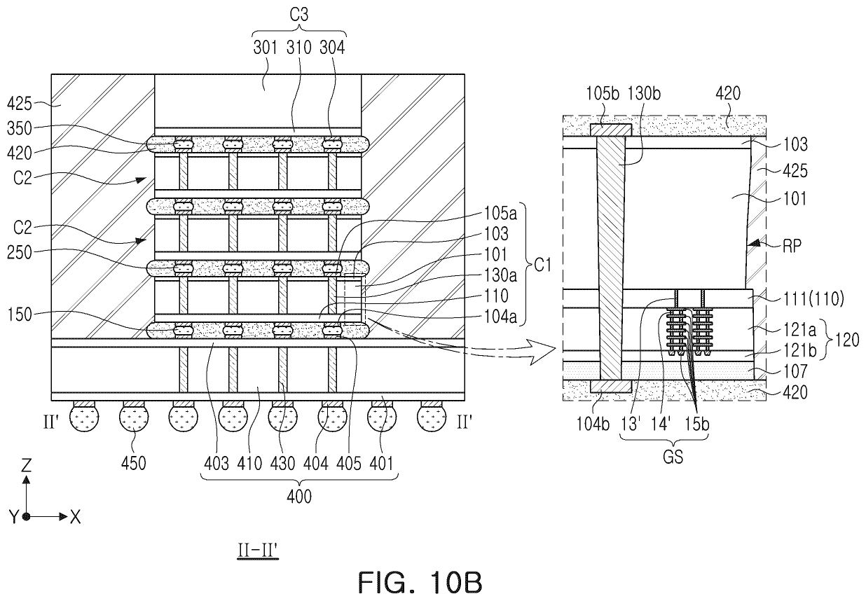

FIG. 10A is a plan view illustrating a semiconductor package according to an example embodiment.

FIG. 10B is a cross-sectional view of the semiconductor package of FIG. 10A, taken along line II-II′.

Referring to FIGS. 10A and 10B, a semiconductor package 1000 of an example embodiment may include a plurality of semiconductor chips C1, C2, and C3 on a base chip 400, bump structures (150, 250, and 350), at least one adhesive layer 420, and an encapsulant 425. The plurality of semiconductor chips C1, C2, and C3 may have the same or similar characteristics as the semiconductor devices 100, 100a, 100b, 100c, and 100d described with reference to FIGS. 1 to 9. The area indicated by reference numeral 300 in FIG. 10A corresponds to an area occupied by the plurality of semiconductor chips C1, C2, and C3 in a plan view.

The plurality of semiconductor chips C1, C2, and C3 may be configured as memory chips or memory elements that store or output data based on an address command, a control command, or the like, received from the base chip 400. For example, the plurality of semiconductor chips C1, C2, and C3 may include a volatile memory element such as a DRAM or an SRAM, or a non-volatile memory element such as a PRAM, an MRAM, an FeRAM, or an RRAM. Among the plurality of semiconductor chips C1, C2, and C3, an uppermost semiconductor chip C3 (hereinafter, “third semiconductor chip”) may not include a through-via, and a back surface thereof may be exposed from the encapsulant 425, but are not limited thereto.

The plurality of semiconductor chips C1, C2, and C3 may include a first semiconductor chip C1, at least one second semiconductor chip C2, and a third semiconductor chip C3, sequentially stacked on the base chip 400.

The base chip 400 may include a substrate 401, an upper protective layer 403, upper pads 405 and lower pads 404, a device layer 410, and through-electrodes 430. The base chip 400 may be, for example, a buffer chip including a plurality of logic devices and/or memory elements in the device layer 410. Therefore, the base chip 400 may externally transmit a signal from the plurality of semiconductor chips C1, C2, and C3 stacked thereon, and may also transmit a signal and power from the outside to the plurality of semiconductor chips C1, C2, and C3. The base chip 400 may perform both a logic function and a memory function through the logic devices and the memory elements, but according to an example embodiment, the base chip 400 may also perform only a logic function by including only the logic devices.

The substrate 401 may include, for example, a semiconductor element such as silicon or germanium (Ge), or a compound semiconductor such as silicon carbide (SiC), gallium arsenide (GaAs), indium arsenide (InAs), or indium phosphide (InP). The substrate 401 may have a silicon-on-insulator (SOI) structure. The substrate 401 may include a conductive region, for example, a well doped with impurities, or a structure doped with impurities. The substrate 401 may include various device isolation structures such as a shallow trench isolation (STI) structure.

The upper protective layer 403 may be formed on an upper surface of the substrate 401, and may protect the substrate 401. The upper protective layer 403 may be formed as an insulating layer such as a silicon oxide film, a silicon nitride film, a silicon oxynitride film, or the like, but a material of the upper protective layer 403 is not limited to those materials. For example, the upper protective layer 403 may be formed of or include a polymer such as polyimide (PI) or photosensitive polyimide (PSPI). Although not illustrated in the drawings, a lower protective layer may be further formed on a lower surface of the device layer 410.

The upper pads 405 may be disposed on an upper surface of the base chip 400 (or on the upper protective layer 403). The lower pads 404 may be disposed on a lower surface of the base chip 400 (or below the device layer 410), and may include a material similar to the upper pads 405.

The device layer 410 may be disposed on a lower surface of the substrate 401, and may include various types of elements. For example, the device layer 410 may include various active components and/or passive components such as a field effect transistor (FET) such as a planar FET, a FinFET, or the like, a memory element such as a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), a resistive random access memory (RRAM), or the like, a logic element such as an AND, an OR, a NOT, or the like, a system large scale integration (LSI), a CMOS imaging sensor (CIS), or a micro-electro-mechanical systems (MEMS).

The device layer 410 may include an interlayer insulating layer (not illustrated) and a multilayer interconnection layer (not illustrated) on the devices described above. The interlayer insulating layer (not illustrated) may include silicon oxide or silicon nitride. The multilayer interconnection layer (not illustrated) may include a multilayer interconnection and/or a vertical contact. The multilayer interconnection layer (not illustrated) may connect elements of the device layer 410 to each other, may connect the elements to a conductive region of the substrate 401, or may connect the elements to the lower pad 404.

The through-electrodes 430 may penetrate the substrate 401 in the vertical direction (Z-direction), and may provide an electrical path connecting the upper pad 405 and the lower pads 404. The through-electrodes 430 may be electrically connected to the plurality of semiconductor chips C1, C2, and C3. The through-electrodes 430 may include a conductive plug and a barrier film surrounding the same. The conductive plug may include a metal material, such as tungsten (W), titanium (Ti), aluminum (Al), or copper (Cu). The conductive plug may be formed by a plating process, a PVD process, or a CVD process. The barrier film may include titanium (Ti), titanium nitride (TiN), tantalum (Ta), or tantalum nitride (TaN), and may be formed by a plating process, a PVD process, or a CVD process. A side insulating film (not illustrated) including an insulating material such as silicon oxide, silicon nitride, silicon oxynitride, or the like (for example, a high aspect ratio process (HARP) oxide) may be formed between side surfaces of the through-electrodes 430 and the substrate 401.

Connection bumps 450 may be disposed below the base chip 400. The connection bumps 450 may be electrically connected to the plurality of semiconductor chips C1, C2, and C3 through the through-electrodes 430. The connection bumps 450 may include, for example, tin (Sn) or an alloy including tin (Sn) (e.g., Sn—Ag—Cu). According to an example embodiment, the connection bumps 450 may have a form in which a metal pillar and a solder ball are combined. The connection bumps 450 may be electrically connected to an external device such as a module substrate, a system board, or the like. The base chip 400 may have a width, greater than a width of each of the plurality of semiconductor chips C1, C2, and C3 in the horizontal direction (e.g., X-direction and/or Y-direction). At least a portion of the connecting bumps 450 and at least a portion of the lower pads 404 may be disposed in a position not overlapping the plurality of semiconductor chips C1, C2, and C3 in the vertical direction (Z-direction).

The first semiconductor chip C1 and the at least one second semiconductor chip C2 may have the same or similar characteristics as the semiconductor devices 100, 100a, 100b, 100c, and 100d described with reference to FIGS. 1 to 9.

The third semiconductor chip C3 may be disposed on an uppermost second semiconductor chip C2, and may include a substrate 301, a front protective layer (not illustrated), front pads 304 disposed at a front side, a device layer 310, and an interconnection layer (not illustrated).

The substrate 301 and the device layer 310 may have the same or similar characteristics as the substrate 401 and the device layer 410 of the base chip 400 described above, and thus, a redundant description may be omitted. The front protective layer (not illustrated) may have the same or similar characteristics as the front protective layer 107, and thus, a redundant description may be omitted. The interconnection layer (not illustrated) may have the same or similar characteristics as the interconnection layer 120, and thus, a redundant description may be omitted.

First to third bump structures 150, 250, and 350 may be disposed below the first semiconductor chip C1, below at least one second semiconductor chip C2, and below the third semiconductor chip C3, respectively. The first to third bump structures 150, 250, and 350 may include, for example, tin (Sn), indium (In), bismuth (Bi), antimony (Sb), copper (Cu), silver (Ag), zinc (Zn), lead (Pb), or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like.

The adhesive layers 420 may surround connection bumps (150, 250, and 350) disposed between the plurality of semiconductor chips C1, C2, and C3, and may fix the plurality of semiconductor chips C1, C2, and C3 on the base chip 400. The adhesive layers 420 may be a non-conductive film (NCF), but are not limited thereto, and may include, for example, all types of polymer films as to which a thermocompression process may be performed.

The encapsulant 425 may seal the plurality of semiconductor chips C1, C2, and C3 on the base chip 400. The encapsulant 425 may be formed to expose a back surface of the third semiconductor chip C3. According to an example embodiment, the encapsulant 425 may be formed to cover the back surface of the third semiconductor chip C3. The encapsulant 425 may be formed of an insulating material such as, for example, an epoxy mold compound (EMC), but a material of the encapsulant 425 is not particularly limited.

The encapsulant 425 may surround side surfaces of the plurality of semiconductor chips C1, C2, and C3. For example, the encapsulant 425 may fill a recess portion RP formed in at least one of the side surfaces of the plurality of semiconductor chips C1, C2, and C3.

When at least one of the plurality of semiconductor chips C1, C2, and C3 includes the semiconductor device 100, 100a, or 100b of FIGS. 4 to 6, the encapsulant 425 may fill the recess portion RP, and may be in contact with an upper surface of the device layer.

When at least one of the plurality of semiconductor chips C1, C2, and C3 includes the semiconductor device 100c of FIG. 8, the encapsulant 425 may fill the first and second recess portions RP1 and RP2, and may be in contact with a lower surface of the semiconductor substrate 101 and the upper surface of the device layer 110.

If at least one of the plurality of semiconductor chips C1, C2, and C3 may include the semiconductor device 100d of FIG. 9, the encapsulant 425 may fill first to third recess portions RP1, RP2, and RP3, and may be in contact with the lower surface of the semiconductor substrate 101 and the upper surface of the interconnection layer 120.

According to an example embodiment, a heat dissipation structure (not illustrated) may be disposed in an upper portion of the encapsulant 425. The heat dissipation structure (not illustrated) may control warpage of the semiconductor package 1000, and may release heat generated from the plurality of semiconductor chips C1, C2, and C3 to the outside.

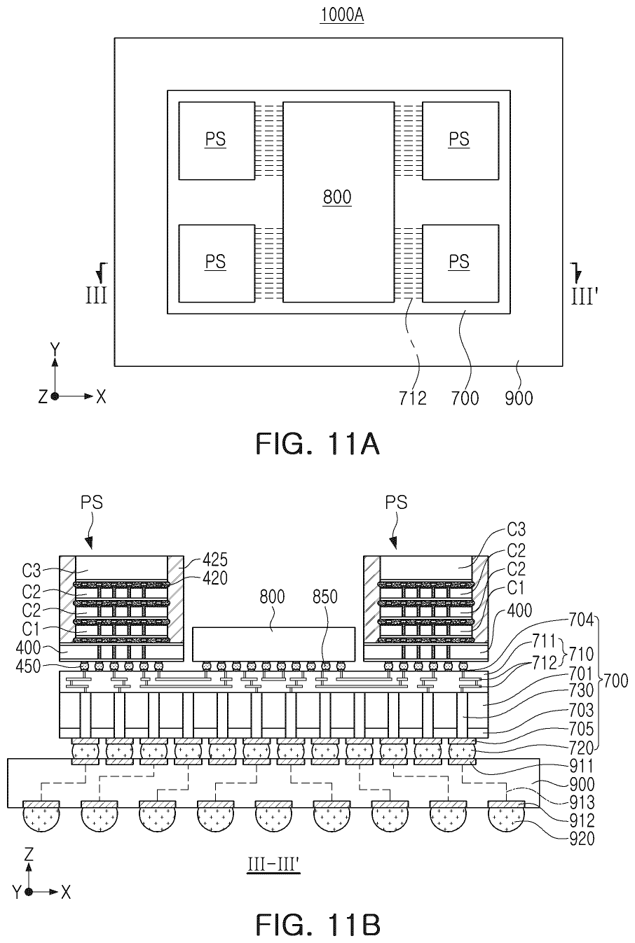

FIG. 11A is a plan view illustrating a semiconductor package according to an example embodiment.

FIG. 11B is a cross-sectional view of the semiconductor package of FIG. 11A, taken along line III-III′.

Referring to FIGS. 11A and 11B, a semiconductor package 1000A may include a package substrate 900, an interposer substrate 700, at least one chip structure PS, and a processor chip 800. The chip structure PS may have the same or similar characteristics as the semiconductor packages 1000 described with reference to FIGS. 1 to 10B. For example, a plurality of semiconductor chips C1, C2, and C3 of the chip structure PS may have the same or similar characteristics as the semiconductor devices 100, 100a, 100b, 100c, and 100d described with reference to FIGS. 1 to 9.

The package substrate 900 may be a support substrate on which the interposer substrate 700, the processor chip 800, and the chip structure PS are mounted, and may be a semiconductor package substrate including a printed circuit board (PCB), a ceramic substrate, a glass substrate, a tape interconnection substrate, or the like. A body of the package substrate 900 may include different materials, depending on a type of the substrate. For example, the package substrate 900 may be a printed circuit board, which includes a copper-clad laminate or a structure in which an interconnection layer is additionally stacked on one side or both sides of the copper-clad laminate.

The package substrate 900 may include a lower terminal 912, an upper terminal 911, and a redistribution circuit 913. The upper terminal 911, the lower terminal 912, and the redistribution circuit 913 may form an electrical path connecting a lower surface and an upper surface of the package substrate 900. The upper terminal 911, the lower terminal 912, and the redistribution circuit 913 may include a metal material, for example, at least one metal from among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C), or an alloy including two or more metals. An external connection terminal 920 connected to the lower terminal 912 may be disposed on the lower surface of the package substrate 900. The external connection terminal 920 may include tin (Sn), indium (In), bismuth (Bi), antimony (Sb), copper (Cu), silver (Ag), zinc (Zn), lead (Pb), and/or an alloy thereof.

The interposer substrate 700 may include a substrate 701, a lower protective layer 703, a lower pad 705, an interconnection structure 710, a metal bump 720, and a through-via 730. The chip structure PS and the processor chip 800 may be electrically connected to each other via the interposer substrate 700. The substrate 701 may be formed of, for example, one of a silicon substrate, an organic substrate, a plastic substrate, or a glass substrate. When the substrate 701 is a silicon substrate, the interposer substrate 700 may be referred to as a silicon interposer. Unlike those illustrated in the drawings, when the substrate 701 is an organic substrate, the interposer substrate 700 may be referred to as a panel interposer.

The lower protective layer 703 may be disposed on a lower surface of the substrate 701, and the lower pad 705 may be disposed below the lower protective layer 703. The lower pad 705 may be connected to the through-via 730. The chip structure PS and the processor chip 800 may be electrically connected to the package substrate 900 through metal bumps 720 disposed below the lower pad 705.

The interconnection structure 710 may be disposed on an upper surface of the substrate 701, and may include an interlayer insulating layer 711 and a single-layer or multilayer interconnection structure 712. When the interconnection structure 710 is formed of a multi-layer interconnection structure, interconnection patterns of different layers may be connected to each other through a contact via.

The through-via 730 may extend from the upper surface of the substrate 701 to the lower surface of the substrate 701, and may penetrate the substrate 701. In some example embodiments, the through-via 730 may extend into the interconnection structure 710, and may be electrically connected to interconnections 712 of the interconnection structure 710. When the substrate 701 is silicon, the through-via 730 may be referred to as a TSV. Depending on example embodiments, the interposer substrate 700 may include only an interconnection structure therein, and may not include a through-via.

The interposer substrate 700 may be used to convert or transmit an input electrical signal between the package substrate 900 and the chip structure PS or the processor chip 800. Therefore, the interposer substrate 700 may not include a component such as an active component, a passive component, or the like. In addition, according to an example embodiment, the interconnection structure 710 may be disposed below the through-via 730. For example, a positional relationship between the interconnection structure 710 and the through-via 730 may be relative.

The metal bump 720 may electrically connect the interposer substrate 700 and the package substrate 900. The chip structure PS may be electrically connected to the metal bump 720 through the interconnections of the interconnection structure 710 and the through-via 730. According to an example embodiment, the lower pads 705 used for power or ground may be integrated and connected together to the metal bumps 720, and thus the number of lower pads 705 may be greater than the number of metal bumps 720.

The processor chip 800 may include, for example, a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), etc. Connection bumps 850 may be disposed below the processor chip 800.

According to an example embodiment, the semiconductor package 1000A may further include an inner encapsulant covering the chip structure PS and the processor chip 800 on the interposer substrate 700. In addition, the semiconductor package 1000A may further include an outer encapsulant covering the interposer substrate 700 and the inner encapsulant on the package substrate 900. The outer encapsulant and the inner encapsulant may be formed together, and may not be distinguished from each other. According to an example embodiment, the semiconductor package 1000A may further include a heat dissipation structure covering the chip structure PS and the processor chip 800.

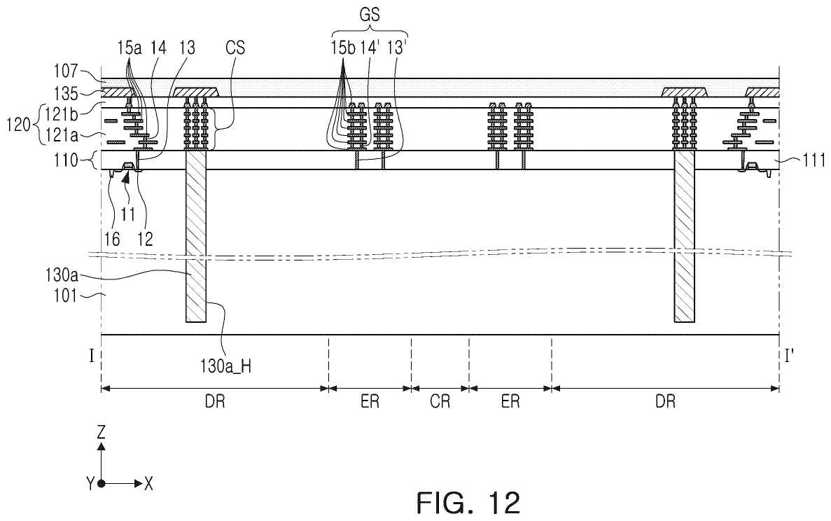

FIGS. 12 to 16 are cross-sectional views illustrating a process sequence for explaining a method of manufacturing a semiconductor package according to an example embodiment.

Referring to FIG. 12, a semiconductor substrate 101, a device layer 110 on the semiconductor substrate 101, a through-via 130a penetrating the semiconductor substrate 101 and the device layer 110, an interconnection layer 120 on the device layer 110, an upper conductive pattern 135 on the interconnection layer 120, and a front protective layer 107 covering the upper conductive pattern 135 on the interconnection layer 120 may be formed.

The semiconductor substrate 101 may be provided, and the device layer 110 may be formed on the semiconductor substrate 101. Integrated circuit devices 11, a conductive region 12, and an isolation region 16 may be formed in a device region DR on a semiconductor substrate 101, and an insulating layer 111 covering the integrated circuit devices 11 may be formed on the semiconductor substrate 101. The insulating layer 111 may include silicon oxide, silicon nitride, silicon oxynitride, or a combination thereof.

Thereafter, connection layers 13 and 13′ penetrating the insulating layer 111 may be formed, and a via hole 130a_H penetrating the insulating layer 111 and a portion of the semiconductor substrate 101 may be formed. A conductive material may be filled in the via hole 130a_H to form a through-via 130a.

The interconnection layer 120 may be formed on the device layer 110. An interlayer insulating layer 121a covering a plurality of conductive patterns 15a and 15b, which include an uppermost conductive pattern, may be formed on the device layer 110, and an insulating layer 121b covering the uppermost conductive pattern may be formed on the interlayer insulating layer 121a. Interconnection patterns 15a may be formed on a conductive structure 13 and the through-via 130a in the device region DR, and guard-ring patterns 15b may be formed on dummy connection layers 13′ in an edge region ER. Therefore, an interconnection structure CS in the device region DR may be defined, and a guard-ring structure GS in the edge region ER may be defined. Thereafter, a conductive via penetrating the insulating layer 121b and connected to the uppermost conductive pattern may be formed.

The conductive pattern 135 may be formed on the interconnection layer 120. The conductive pattern 135 may be formed on the conductive via in the device region DR.

The front protective layer 107 may be formed on the interconnection layer 120. The front protective layer 107 may cover the interconnection structure CS and the conductive pattern 135 in the device region DR, and may cover the guard-ring structure GS in the edge region ER. Referring to FIG. 3B together, a lower pad 136 including a via portion penetrating at least a portion of the front protective layer 107 and connected to the conductive pattern 135 and a pad portion covering the via portion may be formed. Thereafter, a carrier substrate (not illustrated) may be provided on the front protective layer 107.

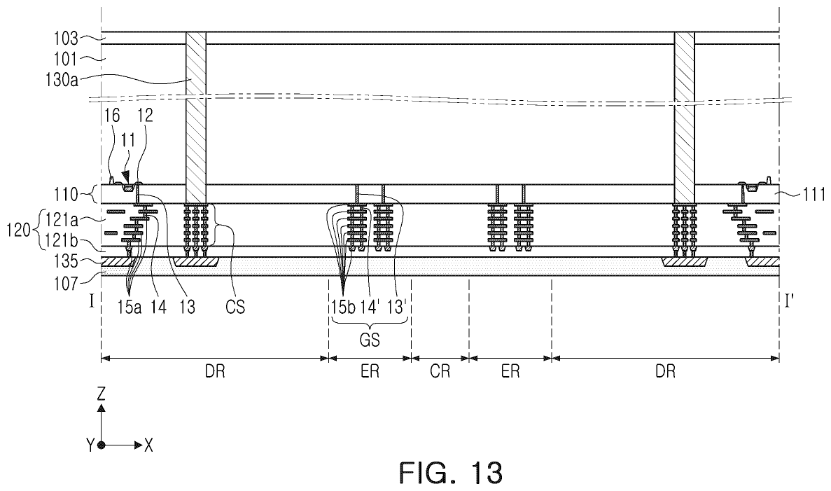

Referring to FIG. 13, the back protective layer 103 may be formed to cover a back surface of the semiconductor substrate 101 and surround the through-via 130a.

For example, the resultant structure of FIG. 12 may be flipped upside down A portion of the semiconductor substrate 101 may be removed to expose the through-via 130a by a certain thickness. Thereafter, the back protective layer 103 covering the back surface of the semiconductor substrate 101 and surrounding the through-via 130a may be formed.

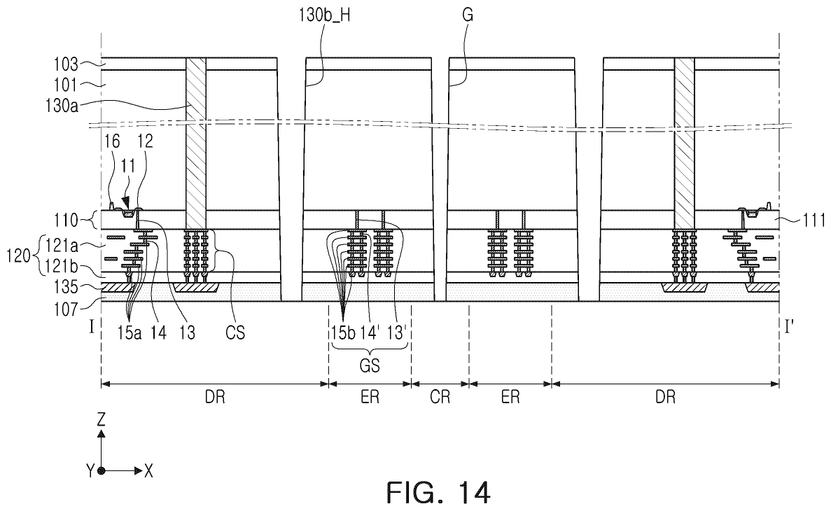

Referring to FIG. 14, a via hole 130b_H may be formed in the device region DR, and a dicing groove G may be formed in a cutting region CR.

The via hole 130b_H and the dicing groove G penetrating from an upper surface of the back protective layer 103 to a lower surface of the front protective layer 107 may be formed in the device region DR and the cutting region CR, respectively.

A width of the via hole 130b_H in the horizontal direction (e.g., X-direction and/or Y-direction) may be greater than a width of the dicing groove G in the horizontal direction. A cross-section of the via hole 130b_H and the dicing groove G in the horizontal direction may have a circular shape, but is not limited thereto.

Referring to FIG. 15, a conductive material 130′ may be filled in the via hole 130b_H and the dicing groove G.

The conductive material 130′ may include tungsten (W), titanium (Ti), aluminum (Al), or copper (Cu). The conductive material 130′ may be formed by a plating process, a PVD process, or a CVD process.

A void V may be formed in the dicing groove G, and an overhang OH may be formed on the dicing groove G. This may be because the width of the dicing groove G is smaller than the width of the via hole 130b_H. The void V may not be formed in the via hole 130b_H because of the relatively greater horizontal width of the via hole 130b_H.

A longitudinal direction of the void V may be substantially the same as a longitudinal direction of the dicing groove G. In this case, the longitudinal direction may mean the vertical direction (e.g., Z-direction). The width of the void V may decrease in the longitudinal direction.

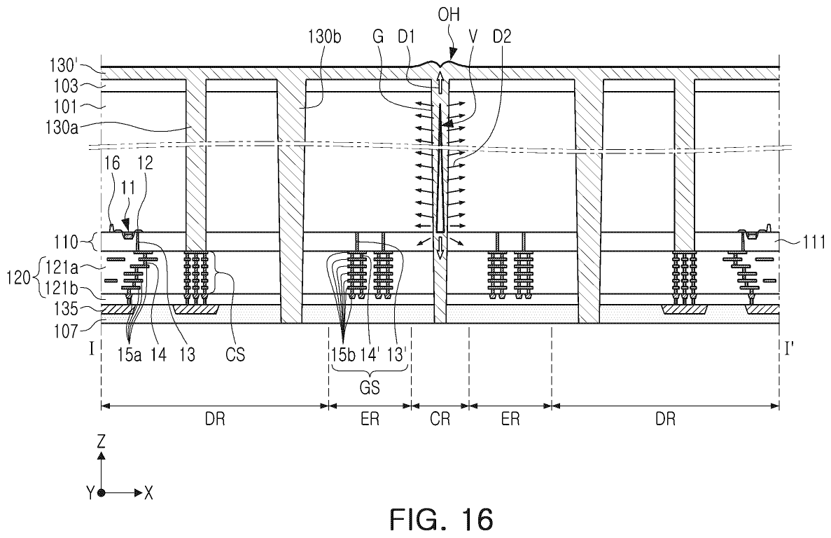

Referring to FIG. 16, a dicing process may be performed.

The dicing process according to some example embodiments of the present inventive concepts may include an annealing process performed within a desired (or alternatively, predetermined) temperature management range. During the annealing process, the void V may expand due to a difference in coefficient of thermal expansion between the conductive material 130′ in the dicing groove G and a material of the semiconductor substrate 101. The void V may expand in the direction D2 perpendicular to a surface (e.g., a boundary) thereof. In other words, the void V may expand in a direction parallel to a horizontal direction (e.g., X-direction).

Stress caused by the expanded void V may be transmitted in the direction D1, parallel to the longitudinal direction. Therefore, a semiconductor substrate W (FIG. 1) may be diced into a plurality of semiconductor chips 100 (FIG. 3B), and a separate laser irradiation process and a separate dicing machine may not be needed in the dicing process according to some example embodiments of the present inventive concepts. A recess portion RP (FIG. 4) may be defined on a side surface of the semiconductor device 100 (FIG. 3B) by the void V expanded in the second direction D2. The recess portion RP may be analyzed, for example, by focused ion beam (FIB) equipment. Afterwards, the conductive material 130′ on a side surface of the semiconductor device may be removed. Therefore, the conductive material 130′ in the recess portion RP (FIG. 4) may also be removed, but a portion thereof may remain (see FIG. 6).

According to some example embodiments, a semiconductor device having improved a dicing property, and a semiconductor package including the same, may be provided by forming a dicing groove in a scribe lane of a semiconductor substrate.

According to an example embodiment of the present inventive concepts, a method of manufacturing a semiconductor package includes forming a device layer on a first surface of a semiconductor substrate, the substrate including a device region and a cutting region, forming a through-via penetrating the semiconductor substrate and the device layer, forming an interconnection layer on the device layer, forming an upper conductive pattern on the interconnection layer, forming a front protective layer covering the upper conductive pattern on the interconnection layer, removing a second surface of the semiconductor substrate to expose the through-via by a certain thickness, the second surface being opposite to the first surface, forming a back protective layer to cover the second surface of the semiconductor substrate and surround exposed sidewall of the through-via, forming a via hole in the device region and a dicing groove in the cutting region, filling the via hole and the dicing groove with a conductive material to selectively form a void in the dicing region, and performing a dicing process using the void formed in the dicing groove to form the semiconductor package.

A width of the via hole in a horizontal direction may be greater than a width of the dicing groove in the horizontal direction.

Various advantages and effects of the present inventive concepts are not limited to the above-described contents, and will be more easily understood in the process of describing specific example embodiments.

While some example embodiments have been illustrated and described above, it will be apparent to those skilled in the art that modifications and variations could be made without departing from the scope of the present inventive concepts as defined by the appended claims.

What is claimed is:

1. A semiconductor device comprising:
an upper structure including a semiconductor substrate having a device region and an edge region on at least one side of the device region;
a lower structure on the upper structure, the lower structure including a device layer, the device layer including a conductive structure and a first insulating layer covering the conductive structure, an interconnection layer being on the device layer, the interconnection layer including a plurality of interconnection pattern layers and a second insulating layer covering the plurality of interconnection pattern layers;
a first through-electrode extending through the semiconductor substrate and the first insulating layer of the device layer and electrically connected to at least one interconnection pattern layer among the plurality of interconnection pattern layers; and
a second through-electrode extending through the semiconductor substrate, the first insulating layer of the device layer, and the second insulating layer of the interconnection layer,
wherein at least one of a side surface of the upper structure or a side surface of the lower structure defines at least one recess portion in the edge region.

2. The semiconductor device of claim 1, wherein a width of the second through-electrode decreases in a direction from an upper surface of the upper structure toward a lower surface of the lower structure.

3. The semiconductor device of claim 1, wherein a width of the second through-electrode increases in a direction from an upper surface of the upper structure toward a lower surface of the lower structure.

4. The semiconductor device of claim 1, further comprising:
an upper pad on the second through-electrode, and
a lower pad below the second through-electrode.

5. The semiconductor device of claim 1, wherein
in the edge region, the side surface of the upper structure includes a first region and a second region on the first region, and
the at least one recess portion includes a first recess portion in the first region.

6. The semiconductor device of claim 5, wherein a ratio of a maximum length of the first recess portion relative to a thickness of the semiconductor substrate is in a range of about 0.4 to about 0.8.

7. The semiconductor device of claim 5, wherein a width of the first recess portion increases toward a lower surface of the semiconductor substrate of the upper structure.

8. The semiconductor device of claim 5, wherein surface roughness of the first region is greater than surface roughness of the second region.

9. The semiconductor device of claim 1, wherein the at least one recess portion includes a plurality of recess portions including a first recess portion on the side surface of the upper structure and a second recess portion on the side surface of the lower structure.

10. The semiconductor device of claim 9, wherein, in a horizontal direction, a maximum width of the first recess portion is different from a maximum width of the second recess portion.

11. The semiconductor device of claim 1, further comprising:
a conductive material layer on at least a portion of a surface of the at least one recess portion.

12. A semiconductor device comprising:
an upper structure including a semiconductor substrate having a device region and an edge region on at least one side of the device region; and
a lower structure on the upper structure, the lower structure including a device layer, the device layer including a conductive structure and a first insulating layer covering the conductive structure, an interconnection layer being on the device layer, the interconnection layer including a plurality of conductive pattern layers and a second insulating layer covering the plurality of conductive pattern layers,
wherein a side surface of the upper structure and a side surface of the lower structure define a plurality of recess portions in the edge region.

13. The semiconductor device of claim 12, wherein the first insulating layer includes a material having a first coefficient of thermal expansion, and the semiconductor substrate includes a material having a second coefficient of thermal expansion, and the first coefficient of thermal expansion is smaller than the second coefficient of thermal expansion.

14. The semiconductor device of claim 13, wherein the first insulating layer includes a material having a first coefficient of thermal expansion, the second insulating layer includes a material having a third coefficient of thermal expansion, and the first coefficient of thermal expansion is smaller than the third coefficient of thermal expansion.

15. The semiconductor device of claim 12, wherein
the plurality of recess portions include a first recess portion and a second recess portion, the first recess portion defined on a side surface of the semiconductor substrate of the upper structure, and the second recess portion defined on a side surface of the first insulating layer of the device layer of the lower structure, and
a step difference is defined between the first recess portion and second recess portion.

16. The semiconductor device of claim 15, wherein a maximum width of the second recess portion is greater than a maximum width of the first recess portion.

17. The semiconductor device of claim 15, wherein
the plurality of recess portions further include a third recess portion defined on a side surface of the second insulating layer, and
a step difference is defined between the second recess portion and third recess portion.

18. The semiconductor device of claim 17, wherein a maximum width of the second recess portion is greater than a maximum width of each of the first and third recess portions.

19. A semiconductor device comprising:
a semiconductor substrate including a device region and an edge region surrounding the device region;
a device layer on the semiconductor substrate, the device layer including a conductive structure and a first insulating layer covering the conductive structure;
an interconnection layer on the device layer, the interconnection layer including a plurality of conductive pattern layers that are vertically stacked and a second insulating layer covering the plurality of conductive pattern layers; and
a through-electrode extending through the semiconductor substrate, the first insulating layer of the device layer, and the second insulating layer of the interconnection layer,
wherein the edge region includes a recess portion in the edge region, the recess portion including a first portion defined by a side surface of the semiconductor substrate, and
a first step difference is defined between a side surface of the first portion and a side surface of the first insulating layer.

20. The semiconductor device of claim 19, wherein
the recess portion further includes a second portion defined by the side surface of the first insulating layer, and
a second step difference is defined between a side surface of the second portion and a side surface of the second insulating layer.
